(19) United States
(12) Patent Application Publication
(10) Pub. No.: US 2015/0271941 A1
(43) Pub. Date: Sep. 24, 2015

(54) ELECTRONIC DEVICE

(71) Applicant: HON HAI PRECISION INDUSTRY CO., LTD., New Taipei (TW)

(72) Inventor: PEN-UEI LU, New Taipei (TW)

(21) Appl. No.: 14/607,469

(22) Filed: Jan. 28, 2015

(30) Foreign Application Priority Data
Mar. 21, 2014 (TW) 103110579

(51) Int. Cl. H05K 7/02

(52) U.S. Cl. CPC H05K 7/02

(57) ABSTRACT

An electronic device includes a housing, a printed circuit board, and a first key. The housing includes a first plate and a second plate received therein. The first plate is parallel to the first plate. The first plate defines a receiving hole. The printed circuit board is received in the housing. The first key includes a press portion mounted on the first plate, a trigger portion, and a support portion. The trigger portion passes through the receiving hole and adjacent to the printed circuit board. The support portion extends from the press portion towards the second plate.

### FIELD

The subject matter herein generally relates to electronic devices, and particularly to an electronic device having at least one key.

### BACKGROUND

An electronic device, such as a smart key of a car, usually has a key provided thereon. The electronic device includes a housing and a printed circuit board (PCB) received in the housing. When the key is pressed, a trigger portion of the key is coupled to the printed circuit board.

### BRIEF DESCRIPTION OF THE DRAWINGS

Implementations of the present technology will now be described, by way of example only, with reference to the attached figures.

FIG. 1 is an isometric view of an embodiment of an electronic device.

FIG. 2 is an exploded, isometric view of the electronic device of FIG. 1.

FIG. 3 is a partial, isometric view of the electronic device of FIG. 1.

FIG. 4 is a cross sectional view taken along a line IV-IV of the electronic device of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is in relation to an electronic device can include a housing, a printed circuit board, and a first key. The housing can include a first plate and a plate received therein. The first plate can be parallel to the first plate. The first plate can define a receiving hole. The printed circuit board can be received in the housing. The first key can include a press portion mounted on the first plate, a trigger portion, and a support portion. The trigger portion can pass through the receiving hole and adjacent to the printed circuit board. The support portion can extend from the press portion towards the second plate.

The present disclosure is in relation to an electronic device can include a housing, a first plate and a second plate within the housing, a printed circuit board within the housing, and a first depressible key. The first plate can be parallel to the second plate and define a receiving hole. The first depressible key can include a press portion, a trigger portion, and a support portion. The press portion can be mounted on the first plate and configured to be depressed by application of force from outside of the housing. The trigger portion can pass through the receiving hole and adjacent to the printed circuit board. The support portion can extend from the press portion towards the second plate. Depression of the press portion can move the trigger portion toward the printed circuit board.

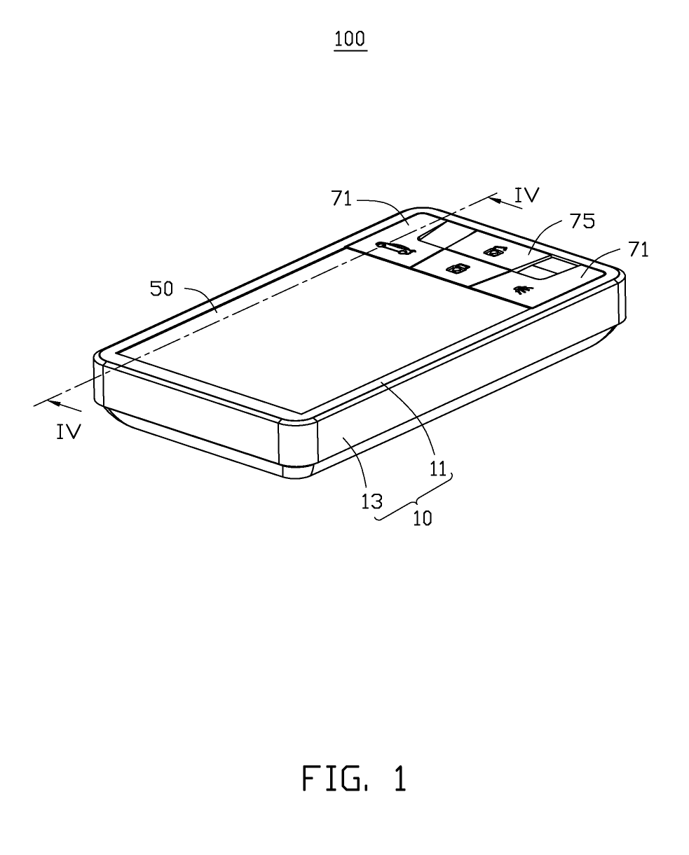

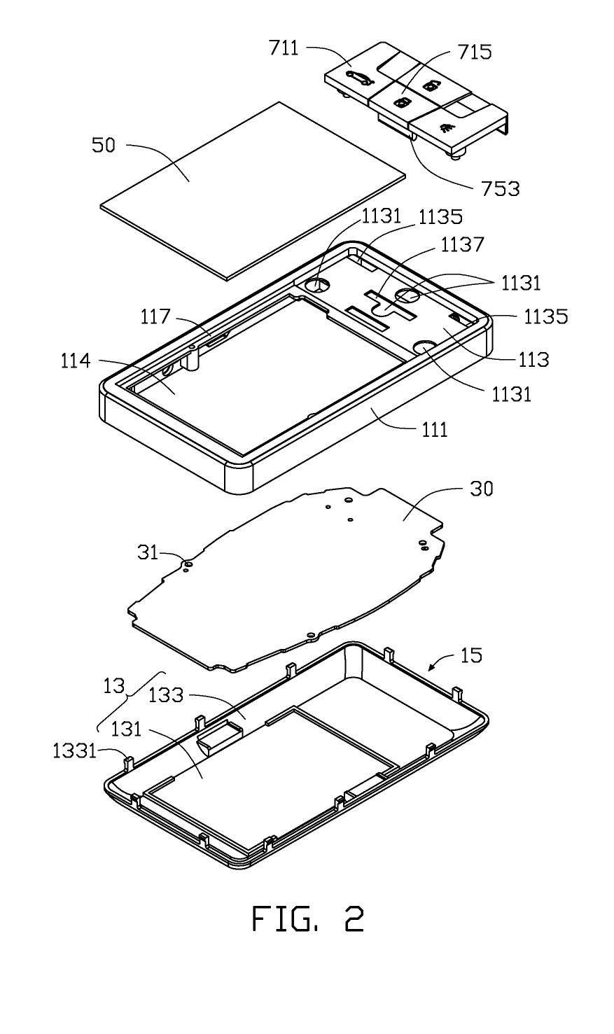

FIG. 1 illustrates an embodiment of an electronic device 100. The electronic device 100 can include a housing 10, a printed circuit board 30 (shown in FIG. 2) received in the housing 10, a display 50 coupled to the housing 10, two first keys 71, and two second keys 75. The first keys 71 and the second keys 75 can be configured to be coupled to the printed circuit board 30. In the illustrated embodiment, the electronic device 100 can be, but not limited to a smart key of a car.

The housing 10 can include a first cover 11 and a second cover 13 coupled to the first cover 11. FIG. 2 illustrates that the first cover 11 can include four sidewalls 111 and a first plate 113 coupled to three of the four sidewalls 111. Two of the sidewalls 111 can be parallel to each other. Another two of the sidewalls can be parallel to each other. The sidewalls 111 can form substantially a rectangular frame and define a receiving chamber 114, cooperatively. The first plate 113 can be positioned at an end portion of the first cover 11. The first plate 113 can be received between two parallel sidewalls 111, and coupled to the two parallel sidewalls 111 and an adjacent sidewall 111. The first plate 113 can be received in the receiving chamber 114 and configured to support the first keys 71 and the second keys 75.

The first plate 113 can define four receiving holes 1131, two first receiving grooves 1135, and two second receiving grooves 1137. Three of the four receiving holes 1131 can be substantially circular. Another one of the four receiving holes 1131 can be substantially semicircular. Two of the circular receiving holes 1131 can be substantially positioned at two corner portions of the first plate 113 and symmetrically about a longitudinal center axis of the first cover 11. Another circular receiving hole 1131 and the semicircular receiving hole 1131 can be substantially positioned at the longitudinal center axis of the first cover 11. The first receiving grooves 1135 can be substantially positioned at another two corner portions of the first plate 113. The second receiving grooves 1137 can be substantially positioned at a center portion of the first plate 113 and parallel to each other. The semicircular receiving hole 1131 can communicate with the adjacent second receiving groove 1137.

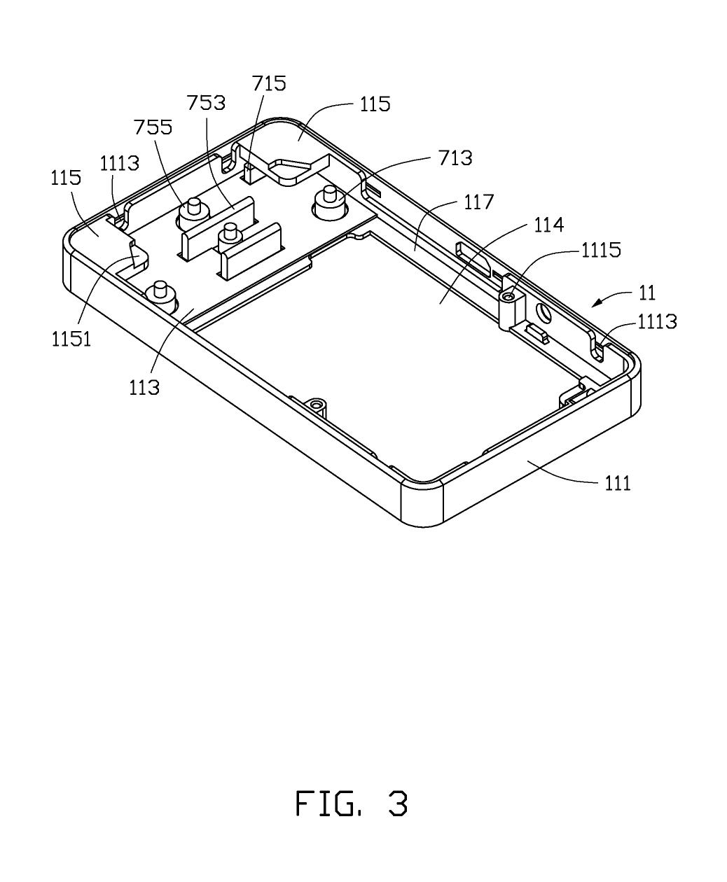

FIG. 3 illustrates that each sidewall 111 can define at least one latching groove 1113. Each of the two parallel sidewalls 111 can define a fixing hole 1115. A mounting portion 117 can inwardly extend from the sidewalls 111. The latching groove 1113 can be substantially a slotted groove (shown in FIG. 3). In the illustrated embodiment, each of two longer sidewalls 111 can define three latching grooves 1113. Each of two shorter sidewalls 111 can define two latching grooves 1113. The latching grooves 1113 of each sidewall 111 can be spaced from each other. The fixing holes 1115 can be respectively defined at the two longer sidewalls 111. The mounting portion 117 can be substantially perpendicular to the sidewalls 111 and configured to support the display 50.

Two second plates 115 can be coupled to the first cover 11 and positioned at two corner portions of the first cover 11. The second plates 115 can be received in the receiving chamber 114 and correspond to the first receiving grooves 1135. Each second plate 115 can be coupled to two adjacent sidewalls 111 and substantially parallel to the first plate 113. The second plates 115 can be positioned between the first plate 113 and the second cover 13. Each second plate 115 can define a depressed portion 1151 at a corner away from the sidewalls 111. The depressed portion 1151 can be substantially trapezoid and configured to receive an edge of the printed circuit plate 30.

Referring to FIG. 2, the second cover 13 can include a bottom wall 131 and an arcuate sidewall 133 extending from edges of the bottom wall 131. A plurality of latching portions 1331 can be coupled to the arcuate sidewall 133 and substantially perpendicular to the bottom wall 131. The latching portions 1331 can be correspond to the latching grooves 1113 and latched to the latching grooves 1113. Thus, the first cover 11 and the second cover 13 can be coupled together. The first cover 11 and the second cover 13 can define a receiving room 15, cooperatively.

The printed circuit board 30 can be substantially rectangular and received in the receiving room 15. The printed circuit board 30 can define two coupling holes 31 corresponding to the fixing holes 1115. The printed circuit board 30 can be partially received in the depressed portion 1151 and positioned in the depressed portion 1151 by friction. Fasteners can be inserted into the fixing holes 1115 and the coupling holes 33, and then fixed to the first cover 11. Thus, the printed circuit board 30 can be coupled to the first cover 11 via the fasteners.

The display 50 can be mounted on the mounting portion 117 and cover the receiving chamber 114. The display 50 can be positioned at a side of the first cover 11 away from the second cover 13. Edges of the display 50 can be coupled to the sidewalls 111 of the first cover 11.

Referring to FIG. 3, the first key 71 and the second keys 75 can be mounted on the first plate 113 and positioned at a side of the first cover 11 away from the second cover 13. An edge of each first key 71 can be adjacent to the sidewall 111. In the illustrated embodiment, each of the first keys 71 and the second keys 75 can be used for different commands. The first keys 71 can be respectively positioned at two corners of the first cover 11 and substantially symmetrically about a longitudinal center axis of the electronic device 100. The second keys 75 can be positioned between the first keys 71 and adjacent to the first keys 71.

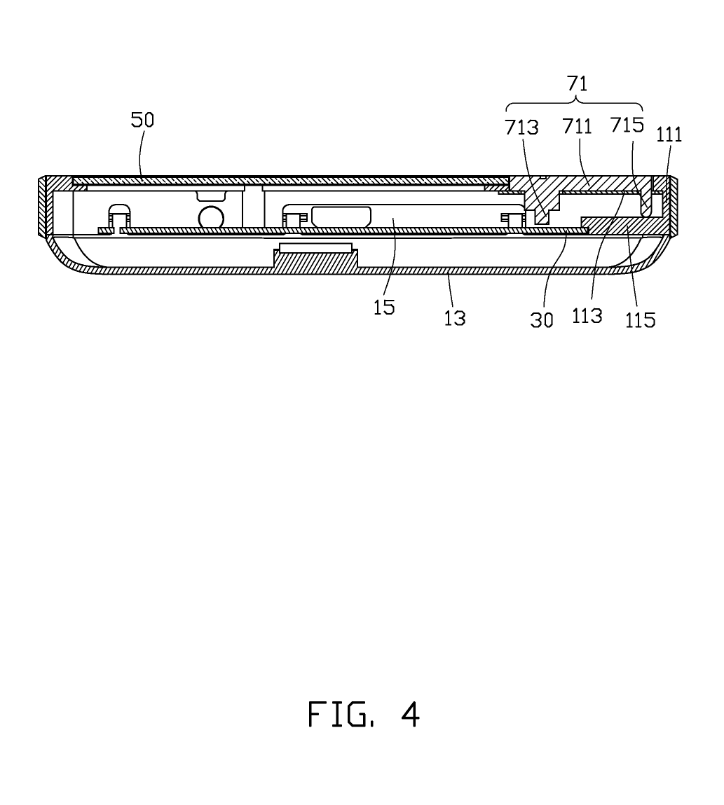

FIG. 4 illustrates that each first key 71 can include a press portion 711, a trigger portion 713, and a support portion 715. The press portion 711, the trigger portion 713, and the support portion 715 can be integrated into one-piece by insert molding. The trigger portion 713 and the support portion 715 can be positioned at opposite ends of the press portion 711. The press portion 711 can be substantially rectangular and mounted on the first plate 113 of the first cover 11. A first end of the press portion 711 can be adjacent to one of the sidewalls 111. A second end of the press portion 711 opposite to the first end can be adjacent to the display 50.

The trigger portion 713 can extend from the press portion 711 towards the printed circuit board 30 and positioned adjacent to the display 50. The trigger portion 713 can pass through the corresponding receiving hole 1131 and adjacent to the printed circuit board 30. When the press portion 711 is pressed, the trigger portion 713 can contact the printed circuit board 30. The support portion 715 can extend from the press portion 711 towards the second plate 115 and positioned between the press portion 711 and the second plate 115. The support portion 715 can be positioned adjacent to one of the sidewalls 111. The support portion 715 can pass through the corresponding first receiving groove 1135 and substantially perpendicularly placed on the corresponding second plate 115. When the first key 71 is pressed, the support portion 715 can act as a support point.

A structure of the second key 75 can be similar to the first key 71. Each second key 75 can include a press portion 751 (shown in FIG. 2), a limiting portion 753 (shown in

FIG. 3), and a trigger portions 755 (shown in FIG. 3). The limiting portion 753 can extend from the press portion 751 towards the printed circuit board 30. The limiting portion 753 can be substantially rectangular and pass through the corresponding second receiving groove 1137 of the first plate 113. Thus, the second key 75 can be coupled to the first plate 113. In the illustrated embodiment, the limiting portions 753 of the second keys 75 can be parallel to each other.

The trigger portion 755 can extend from the press portion 751 towards the printed circuit board 30. The trigger position 755 can be positioned at the longitudinal center axis of the electronic device 100. The trigger portion 755 can pass through the corresponding receiving holes 1131 and positioned adjacent to the printed circuit board 30. When the second key 75 is pressed, the trigger portion 755 can contact the printed circuit board 30. In the illustrated embodiment, one of the trigger portions 755 can be positioned between the limiting portions 753 of the second keys 75. Another one of the trigger portions 755 can be positioned between the limiting portion 753 and the sidewall 111. In the illustrated embodiment, the first keys 71 and the second keys 75 can be made of flexible material, such as rubber.

When in assembly, the first keys 71 and the second keys 75 can be mounted on the first plate 113 of the first cover 11. The trigger portion 713 of each first key 71 and the trigger portion 755 of each second key 75 can be respectively inserted into the receiving holes 1131, respectively. The support portion 715 of each first key 71 can be inserted into the first receiving hole 1131, respectively. The support portion 715 of each first key 71 can be inserted into the first receiving groove 1135. The limiting portion 753 of the second key 75 can be inserted into the second receiving grooves 1137. The printed circuit board 30 can be mounted on the first cover 11. The display 50 can be mounted on the mounting portion 117 of the first cover 11. The second cover 13 can be coupled to the first cover 11 and the printed circuit board 30 can be received in the receiving chamber 15.

When a force is applied to a portion of the press portion 711 deviated the trigger portion 713, the support portion 715 can act as a support point. Thus, the trigger portion 713 of the first key 71 can also move towards the printed circuit board 30.

In at least one embodiment, a number of the first key 71 can be one or more than one. The second keys 75 can be omitted.

The embodiments shown and described above are only examples. Many details are often found in the art such as the other features of an electronic device. Therefore, many such details are neither shown nor described. Even though numerous characteristics and advantages of the present technology have been set forth in the foregoing description, together with details of the structure and function of the present disclosure, the disclosure is illustrative only, and changes may be made in the details, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. An electronic device comprising:
a housing comprising a first plate and a second plate received therein, the first plate parallel to the second plate, the first plate defining a receiving hole;
a printed circuit board received in the housing; and
a first key comprising:
a press portion mounted on the first plate,
a trigger portion passing through the receiving hole and adjacent to the printed circuit board, and
a support portion extending from the press portion towards the second plate.

2. The electronic device of claim 1, wherein the trigger portion and the support portion is positioned at opposite ends of the press portion.

3. The electronic device of claim 1, further comprising a display coupled to the housing, wherein the support portion is positioned adjacent to a sidewall of the housing, the trigger portion is positioned adjacent to the display.

4. The electronic device of claim 1, wherein the first plate further defines a first receiving groove, the support portion passes through the first receiving groove.

5. The electronic device of claim 1, wherein the housing comprises:
a first cover having four sidewalls, the sidewalls defines a receiving chamber, and
a second cover coupled to the first cover,
wherein the first plate is received in the receiving chamber, the second plate is coupled to two adjacent sidewalls of the first cover, the second plate is positioned between the first plate and the second cover, the first cover and the second cover defines a receiving room, cooperatively, the printed circuit board is received in the receiving room.

6. The electronic device of claim 5, wherein each sidewall defines at least one latching groove, the second cover comprises a bottom wall and an arcuate sidewall extending from edges of the bottom wall, a plurality of latching portions are coupled to the arcuate sidewall and substantially perpendicular to the bottom wall, each latching portion is latched to one of the latching groove.

7. The electronic device of claim 5, wherein the printed circuit board is fastened to the first cover.

8. The electronic device of claim 5, wherein the second plate defines a depressed portion at a corner away from the sidewalls, the printed circuit board is partially received in the depressed portion.

9. The electronic device of claim 1, further comprising a second key, the second key comprising:
a press portion;
a limiting portion extending from the press portion towards the printed circuit board; and
a trigger portion extending from the press portion towards the printed circuit board and positioned adjacent to the printed circuit board,
wherein the first plate further defines a second receiving groove, the limiting portion passes through the second receiving groove.

10. The electronic device of claim 1, wherein the electronic device is a smart key of a car.

11. An electronic device comprising:
a housing comprising a first plate and a second plate received therein, the first plate parallel to the second plate;
a printed circuit board received in the housing; and
a first key comprising:
a press portion supported by the first plate,
a trigger portion passing through the first plate and adjacent to the printed circuit board; and
a support portion extending from the press portion towards the second plate.

12. The electronic device of claim 11, wherein the trigger portion and the support portion is positioned at opposite ends of the press portion.

13. The electronic device of claim 11, wherein the housing comprises:
a first cover having four sidewalls, the sidewalls defines a receiving chamber, and
a second cover coupled to the first cover,
wherein the first plate and the second plate are received in the receiving chamber, the second plate is positioned between the first plate and the second cover, the first cover and the second cover defines a receiving room, cooperatively, the printed circuit board is received in the receiving room.

14. The electronic device of claim 13, wherein each sidewall defines at least one latching groove, the second cover comprises a bottom wall and an arcuate sidewall extending from edges of the bottom wall, a plurality of latching portions are coupled to the arcuate sidewall and substantially perpendicular to the bottom wall, each latching portion is latched to one of the latching groove.

15. The electronic device of claim 13, further comprising a display, wherein a mounting portion inwardly extend from the sidewalls, the display is mounted on the mounting portion and cover the receiving chamber.

16. The electronic device of claim 11, wherein the second plate defines a depressed portion at a corner thereof, the printed circuit board is partially received in the depressed portion.

17. The electronic device of claim 16, wherein the depressed portion is substantially trapezoid and configured to receive an edge of the printed circuit plate.

18. The electronic device of claim 11, further comprising a second key, the second key comprising:
a press portion;
a limiting portion extending from the press portion towards the printed circuit board; and
a trigger portion extending from the press portion towards the printed circuit board and positioned adjacent to the printed circuit board.

19. An electronic device comprising:
a housing;
a first plate and a second plate within the housing, the first plate being parallel to the second plate and defining a receiving hole;
a printed circuit board within the housing; and
a first depressible key comprising:
a press portion mounted on the first plate and configured to be depressed by application of force from outside of the housing,
a trigger portion passing through the receiving hole and adjacent to the printed circuit board, and
a support portion extending from the press portion towards the second plate;
wherein depression of the press portion moves the trigger portion toward the printed circuit board.

20. The electronic device of claim 19, further comprising a second key, the second key comprising:
a press portion;
a limiting portion extending from the press portion towards the printed circuit board; and
a trigger portion extending from the press portion towards the printed circuit board and positioned adjacent to the printed circuit board.
